(19) United States
(12) Patent Application Publication
(10) Pub. No.: US 2018/0372793 A1
(43) Pub. Date: Dec. 27, 2018

(54) System and Method for Performing a Test Procedure

(71) Applicant: Bell Helicopter Textron Inc., Fort Worth, TX (US)

(72) Inventors: Sebastien Giroux, St-Joseph-du-lac (CA); Cedric Roche, Saint-Eustache (CA)

(73) Assignee: Bell Helicopter Textron Inc., Fort Worth, TX (US)

(21) Appl. No.: 15/663,804

(22) Filed: Jul. 30, 2017

(30) Foreign Application Priority Data
Jun. 22, 2017 (CA) 2971890

(51) Int. Cl. G01R 31/28; G01R 31/00

(52) U.S. Cl. CPC G01R 31/2834; G01R 31/008

(57) ABSTRACT

A testing system and method are provided. A storage unit has stored therein a test procedure comprising one or more instructions for testing a system under test. A workstation is remotely interfaced with the system under test. The workstation comprises a test unit configured to retrieve the test procedure from the storage unit and to simulate at least one operation on the system under test in real-time for testing the system under test in accordance with the one or more instructions.

### CROSS-REFERENCE TO RELATED APPLICATIONS

This patent application claims priority under 35 USC § 119(e) of Canadian Application No. 2971890, filed on Jun. 22, 2017, the contents of which are hereby incorporated by reference.

### FIELD

Embodiments described herein generally relate to the field of testing, more particularly to performing a Functional Test Procedure (FTP) on an aircraft system.

### BACKGROUND

A Functional Test Procedure (FTP) defines the manner in which a unit under test, such as an aircraft system, should be tested to determine whether the unit under test is functionally sound. Each FTP is typically written for a particular unit under test and comprises a sequence of tests. Based on the FTP, in each test, one or more input signals are applied to terminals of the unit under test and the result output signals are measured and compared to expected results to assess a pass or fail of the FTP test. If an FTP test fails, the test results may be used to diagnose and troubleshoot the faulty unit under test.

In current FTP processes, operators are required to interpret the FTP instructions and perform a number of manual operations accordingly. This usually requires significant travel to and from the aircraft (e.g. to read FTP instructions) and the connector area (e.g. to connect and disconnect connectors). In addition to having a negative impact on operator health and safety, the high degree of physical movement around the aircraft increases the amount of time required to perform the FTP, therefore enhancing the complexity of the overall procedure. Interpretation of the FTP instructions can also result in an increased possibility of human error.

There is therefore a need for an improved system and method for performing a test procedure.

### SUMMARY

In accordance with one aspect, there is provided a system for performing a test procedure. The system comprises a storage unit having stored therein the test procedure comprising one or more instructions for testing a system under test, and a workstation remotely interfaced with the system under test, the workstation comprising a test unit configured to retrieve the test procedure from the storage unit and to simulate at least one operation on the system under test in real-time for testing the system under test in accordance with the one or more instructions.

In accordance with another aspect, there is provided a method for performing a test procedure. The method comprises remotely interfacing a test unit with a system under test, and, using the test unit, retrieving from a storage unit the test procedure comprising one or more instructions for testing the system under test and simulating at least one operation on the system under test in real-time for testing the system under test in accordance with the one or more instructions.

In accordance with another aspect, there is provided a non-transitory computer readable medium having stored thereon program code executable by a processor for retrieving from a storage unit a test procedure comprising one or more instructions for testing a system under test and simulating at least one operation on the system under test in real-time for testing the system under test in accordance with the one or more instructions.

Many further features and combinations thereof concerning the present improvements will appear to those skilled in the art following a reading of the instant disclosure.

### DESCRIPTION OF THE FIGURES

In the figures,

FIG. 1 is a block diagram of an example system for performing a test procedure, in accordance with one embodiment;

FIG. 2A is a front view of the system of FIG. 1 when used for testing an aircraft system, in accordance with one embodiment;

FIG. 2B is a side view of the system of FIG. 1 when used for testing an aircraft system, in accordance with one embodiment;

FIG. 3 is an example embodiment of simulation of an FTP operation by the test unit of FIG. 1 using a switch, in accordance with one embodiment;

FIG. 4 is an example embodiment of a computing device for implementing the test unit of FIG. 1; and

FIG. 5 is a flowchart of an example method for performing a test procedure, in accordance with one embodiment.

It will be noted that throughout the appended drawings, like features are identified by like reference numerals.

### DETAILED DESCRIPTION

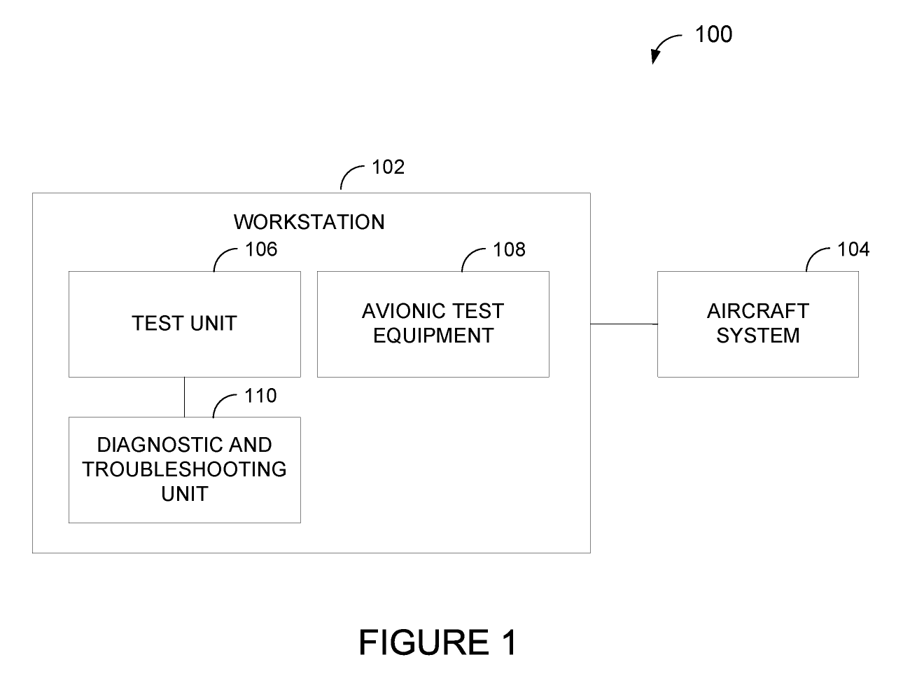

Referring to FIG. 1, an example system 100 for performing a test procedure, in accordance with one embodiment, will now be described. Although the system 100 is illustrated and described herein as being used to test an aircraft system, it should be understood that a variety of other systems may apply. The system 100 may indeed be used to test any electrical or electronic system requiring quality control testing including, but not limited to boat systems, car systems, train systems, and satellite systems. Examples of an aircraft system include, but are not limited to, a hydraulics system, an engine system, a fuel system, a navigation system, a landing gear system, a flap control system, an electricity generating system, and a cabin climate control system.

The illustrated system 100 comprises a workstation 102, onto which a test unit 106 and at least one test equipment, such as avionic test equipment, 108 are integrated, such that the workstation 102 may be customized to a given application or user needs. The workstation 102 is in turn interfaced with a system under test, such as an aircraft system 104, through any suitable means. As will be discussed further below, the test unit 106 and the avionic test equipment 108 may be used to test the aircraft system 104 in accordance with a predefined test procedure (e.g. an FTP), with the test unit 106 being used to implement operations that would typically be performed manually as part of the test procedure and the avionic test equipment 108 being used to perform remaining FTP tests. In one embodiment, the workstation 102 is located outside (e.g. in front of) the aircraft (not shown) and the equipment installed on the workstation 102 is modular so as to be removable for calibration and/or repair purposes.

In one embodiment, the system 100 may be used in aircraft as in 202 with an integrated flight deck. It should however be understood that the system 100 may also be used in aircraft having an analog flight deck. In the latter case, instead of the test unit 106 remaining on the workstation 102 at all times, the test unit 106 may be brought inside the cockpit in order to allow access to devices, such as gauges and switches, provided in the flight deck. As such, the test unit 106 may be provided on the workstation 102 as a standby device or as a portable device.

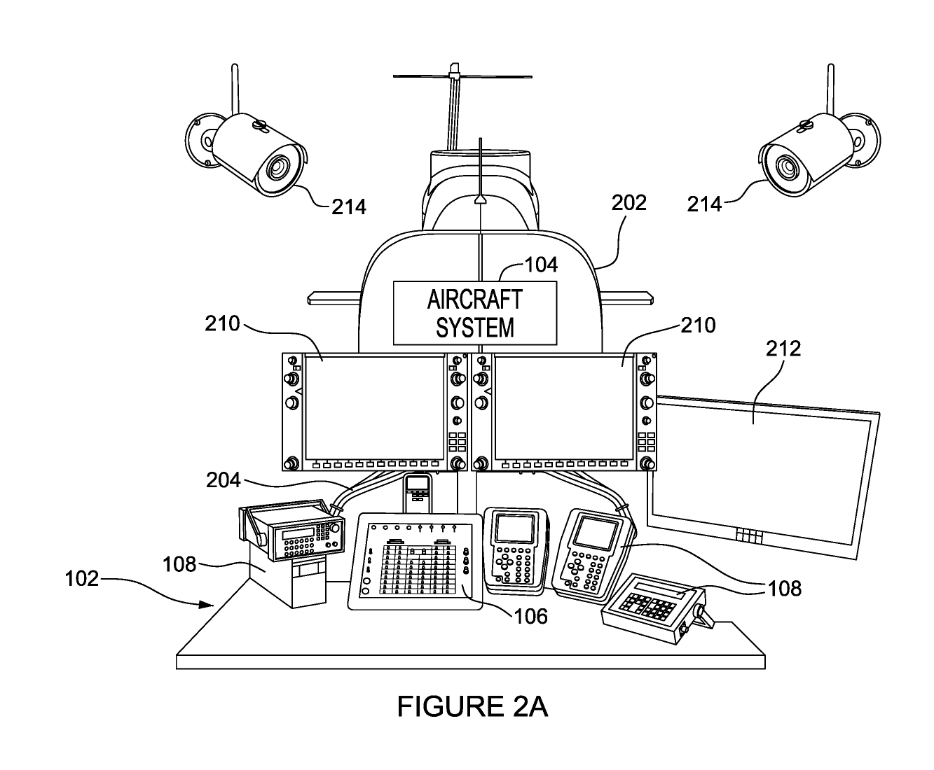

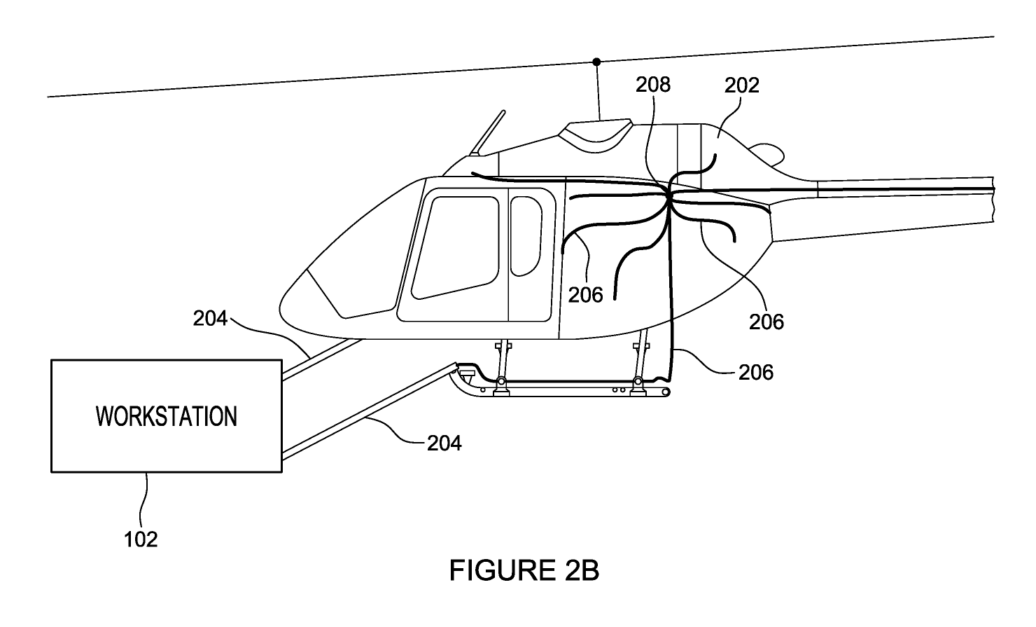

In one embodiment illustrated in FIG. 2A and FIG. 2B, the test unit 106 is interfaced with the aircraft system 104 through one or more attachment means 204 (e.g. solid fixtures, such as metal beams or the like) used to attach the workstation 102 to the aircraft 202.) At least one electrical wiring harness (or patch cable) 206 may be used to connect each connector (not shown) of the aircraft system 104 under test to the workstation 102 (e.g. to the test unit 106). For example, the wiring harness(es) 206 may be connected to a connector disconnect box 208 of the aircraft 202. In this manner, all connecting (and disconnecting) operations may be performed at once when installing (and removing) the wiring harness(es) 206, thereby decreasing the amount of time required to perform the overall test procedure. The wiring harness 206 may comprise a bundle of individual connector wires (not shown) of varying gauges, types, and impedances. The connector wires may be arranged and distributed at various locations within the aircraft 202. In one embodiment, the end connections (not shown) of the harness 206 on the aircraft 202 are determined by the FTP, such that the end connections of the harness 206 are in a specific location but the harness routing between the end connections of the harness 206 and the test unit 106 are not specific. Health and safety as well as harness length are factors used to determine the securing locations of the harness(es) 206.

In one embodiment, the workstation 102 has installed thereon component(s) that are removable from the aircraft 202 for use during the FTP. One or more cameras may then be used to give visual access to any component that cannot (or need not) be removed from the aircraft 202 and installed on the workstation 102. For example, aircraft flight displays as in 210 may be removed from the aircraft 202, installed on the workstation 102, and interfaced with their original connector(s) through an extension harness (not shown). In another embodiment, screens may be installed on the workstation 102 and connected to one or more cameras located inside the cockpit and configured to monitor standby instruments that cannot be taken out of the aircraft 202. Graphic recognition software may be provided on the cameras to allow for results (e.g. readings from the aircraft standby instruments, displays 212, gauges, or the like) to be detected automatically. Visual checks may also be performed (e.g. by an operator) through displays 212 connected to cameras (e.g. Wi-Fi cameras 214) configured to capture image(s) (e.g. photo(s) and/or video(s)) of the aircraft standby instruments. In addition, completion and verification steps may be performed using data bus readers for redundancy.

Backup power (not shown) may also be provided on the workstation 102 to prevent damage to the test equipment (e.g. the test unit 106 and/or the avionic test equipment 108) in the event of a power failure.

In one embodiment, the workstation 102 is used to perform one or more FTP tests of a given test sequence. Provision of the test unit 106 and the avionic test equipment 108 together on the workstation 102 then allows for most of the FTP tests to be centralized and performed from a single location. In order to increase efficiency and standardize troubleshooting, aircraft technical documentation may also be made available on the workstation 102.

In one embodiment, based on the FTP, each manual intervention (e.g. each manual electrical FTP step) to be performed on the aircraft 202 is illustratively performed through the test unit 106 in a centralized manner, as discussed above. For example, the test unit 106 may be configured to automatically (or semi-automatically) simulate operations including, but not limited to, simulating a short to the ground, disconnecting a connector, injecting a signal, a voltage, a current, simulating a resistance, impedance, capacitance, or inductance, and measuring a voltage, current, resistance, impedance, capacitance, or inductance. For this purpose, the workstation 102 may be communicatively coupled to a storage unit (e.g. a memory, not shown) storing the FTP instructions, with the test unit 106 being configured transcribe or convert the written FTP procedure into an electronic version. For example, and as will be discussed further below, if an FTP instruction comprises disconnecting a connector, the test unit 106 generates a control signal that causes a switch to open, thereby recreating the same disconnecting condition but through the test box 106.

In one embodiment, the FTP instructions may be written so as to group together operations requiring an operation to be performed on the aircraft 202. In particular, a first group of FTP instructions may be created, the first group consisting of all FTP tests to be performed using the workstation 102. The first group of FTP instructions could in turn be subdivided into a first subgroup comprising FTP tests (e.g. manual operations) that are to be performed (e.g. simulated) using the test unit 106 and a second subgroup comprising remaining FTP tests that are to be performed using other equipment (e.g. avionic test equipment 108) installed on the workstation 102. A second group of FTP instructions may also be created, the second group of FTP instructions consisting of all FTP tests (e.g. radio checks) that cannot be performed through the workstation 102 as well as FTP tests (e.g. bit tests and manually activated self-tests) that are to be performed to inspect the integrity of the aircraft system 104 subsequent to the first group of FTP instructions being executed.

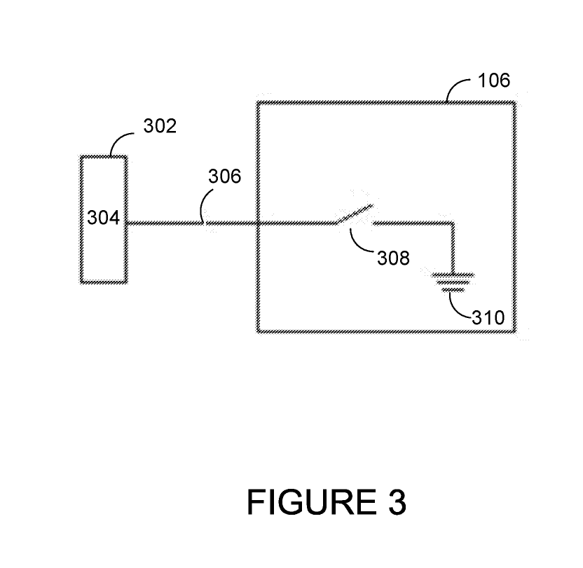

In one embodiment, the manual FTP operations may be semi-automated. For this purpose, the test unit 106 may comprise a plurality of switches (not shown) and may be wired such that each switch creates the necessary condition(s) to perform any required operation as part of the FTP. For example, and as illustrated in FIG. 3, if an operation in the FTP instructs to disconnect connector 302 and inject a ground in pin 304, this manual operation may be simulated using the test unit 106. For this purpose, a patch harness (not shown) may be connected to the connector 302. The patch harness may for example consist of a wire 306 connected in pin 304 and routed to the test unit 106. In the test unit 106, the wire 306 may in turn be connected to a switch 308 that, when activated (i.e. turned ON), may connect the wire 306 to a ground 310. It should be understood that any condition required by the FTP maybe recreated in a similar manner using the test box 106 and other embodiments may therefore apply.

In another embodiment, the need for manual switches may be alleviated by fully automating the manual FTP operations. For this purpose, the test unit 106 may comprise a PLC, a microcontroller, or any other suitable computing device (discussed further below) configured to cause the manual operations to be simulated. Using such a device, the test unit 106 may for example be used to inject a voltage to simulate a transducer and test a fuel system without having to physically fuel the aircraft. The test unit 106 may also be used to simulate any type of measuring device, sensing device, or the like installed on any system, whether electric or otherwise. For example, the test unit 106 may be used to activate a calibrated pressure pump in order to apply a specific pressure level such that when the pump is turned ON, the pump builds a given pressure (e.g. 100 psi). The test unit 106 may then be used to turn the pump ON and OFF when require to automatically simulate a specific pressure in a pressurized system.

In another embodiment, the test unit 106 may be used to simulate emission of a radio-frequency (RF) signal (e.g. instruct hardware installed on the aircraft system 104 to emit the RF signal) in order to test a communication and navigation system of the aircraft. In yet another embodiment, the test unit 106 may be used to program and control an air data test set with a specific sequence (e.g. defined by engineering documentation). The test unit 106 may therefore be used to simulate (e.g. include in the test sequence) and control (e.g. turn ON and/or OFF) any test equipment, including the avionic test equipment 108, which may be electrically controlled to test a given system. For example, the avionic test equipment 108 may be simulated using the test unit 106 and the avionic test equipment may therefore be integrated with the test unit 106 (i.e. not provided separately therefrom as illustrated in FIG. 2A). In one embodiment, a Graphical User Interface (GUI) may be used to receive input data for launching a given test sequence.

Referring back to FIG. 1, in one embodiment, the workstation 102 further comprises a diagnostic and troubleshooting unit 110, which may receive the results of the tests performed using the test unit 106 and/or the other test equipment (e.g. the avionic test equipment 108). For example, the diagnostic and troubleshooting unit 110 may receive one or more output signals from the aircraft system 104 in response to the test being performed using the workstation 102. The test results are then compared to one or more test criteria (e.g. expected result) to assess pass or fail of the test(s). If the test results meet one or more test criteria defined by the test procedure, the diagnostic and troubleshooting unit 110 concludes to success of the test(s). Otherwise, if any test result fails to meet the test criteria, it is determined that the test(s) failed. A troubleshooting sequence may then be automatically initiated to troubleshoot the faulty system. Each step of the troubleshooting sequence may be programmed in advance and stored in memory.

In one embodiment, the diagnostic and troubleshooting unit 110 accesses (e.g. retrieves from a memory and/or database) a wiring diagram of the aircraft system 104 and measures a resistance of electrical wires provided on the aircraft system 104 to determine which part of the aircraft system 104 under test is faulty. Once the faulty wire (or wires) has been identified, the diagnostic and troubleshooting unit 110 may output a signal comprising an indication of a distance at which the wire is broken, thereby allowing for fast location of the problem and quick fix. The diagnostic and troubleshooting unit 110 may also inject one or more signals in the faulty aircraft system 104 to activate relays in order to a complete verification of the functionality of the faulty aircraft system 104. If the diagnostic and troubleshooting unit 110 is unable to determine what or where the faulty condition is, the diagnostic and troubleshooting unit 110 may provide a report to this effect. The report may comprise all the documentation necessary for an operator to carry out the troubleshooting. After the fault has been repaired, the faulty section of the test procedure may be restarted to confirm the integrity and functionality of the previously faulty system.

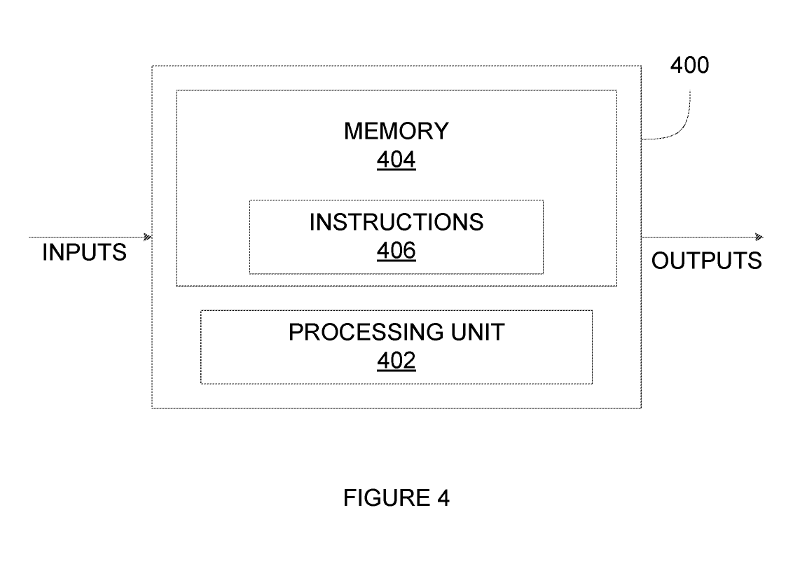

FIG. 4 is an example embodiment of a computing device 400 for implementing the test unit (reference 106 in FIG. 1). It should be understood that the diagnostic and troubleshooting unit (reference 110 in FIG. 1) may also be implemented using the computing device 400. The computing device 400 comprises a processing unit 402 and a memory 404 which has stored therein computer-executable instructions 406. The processing unit 402 may comprise any suitable devices configured to cause a series of steps to be performed such that instructions 406, when executed by the computing device 400 or other programmable apparatus, may cause the functions/acts/steps specified in the methods described herein to be executed. The processing unit 402 may comprise, for example, any type of general-purpose microprocessor or microcontroller, a digital signal processing (DSP) processor, a central processing unit (CPU), an integrated circuit, a field programmable gate array (FPGA), a reconfigurable processor, other suitably programmed or programmable logic circuits, or any combination thereof.

The memory 404 may comprise any suitable known or other machine-readable storage medium. The memory 404 may comprise non-transitory computer readable storage medium, for example, but not limited to, an electronic, magnetic, optical, electromagnetic, infrared, or semiconductor system, apparatus, or device, or any suitable combination of the foregoing. The memory 404 may include a suitable combination of any type of computer memory that is located either internally or externally to device, for example random-access memory (RAM), read-only memory (ROM), compact disc read-only memory (CDROM), electro-optical memory, magneto-optical memory, erasable programmable read-only memory (EPROM), and electrically-erasable programmable read-only memory (EEPROM), Ferroelectric RAM (FRAM) or the like. Memory 404 may comprise any storage means (e.g., devices) suitable for retrievably storing machine-readable instructions 406 executable by processing unit 402.

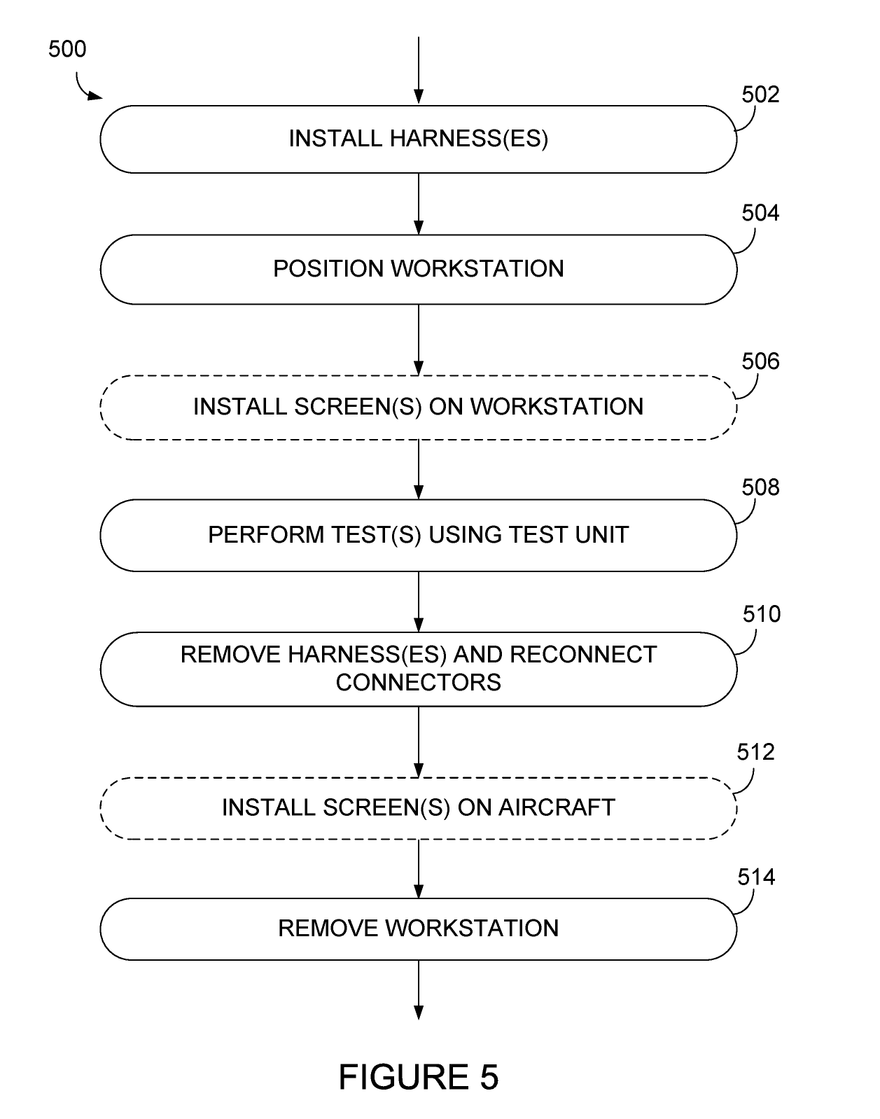

Referring now to FIG. 5, an example method 500 for performing a test procedure will now be described. The illustrated method 500 may be used to perform an FTP on an aircraft system. The method 500 may comprise installing at least one wiring harness (or patch cable(s)) at step 502, e.g. connecting the wiring harness(es) to the aircraft connector disconnect box. The next step 504 is then to put the workstation in place, e.g. electrically interface the workstation with the aircraft system using the wiring harness(es), as discussed herein above. One or more screens may then optionally be installed on the workstation at step 506. This may comprise installing on the workstation flight displays removed from the aircraft and interfacing the flight displays with their original connector(s) through an extension harness. As discussed above with reference to FIG. 2A and FIG. 2B, in one embodiment, no screens are removed from the aircraft and test results are monitored through at least one camera system (e.g. using graphic recognition or a screen connected to Wi-Fi cameras).

The test unit is then used at step 508 to perform one or more tests in accordance with the FTP, as discussed above. Step 508 may comprise simulating (e.g. in a semi- or fully-automated manner, as discussed above) at least one operation on the aircraft system in real-time for testing the aircraft system in accordance with FTP instruction(s) retrieved from memory. Once the FTP has been performed, the wiring harness(es) may be removed and connectors reconnected at step 510. The one or more screens may then be optionally returned to the aircraft and installed thereon at step 512 and the workstation removed at step 514. It becomes apparent that the method 500 may allow to reduce the amount of time required to perform the FTP in addition to decreasing the amount of physical movement around the aircraft and minimizing the possibility of human errors.

The above description is meant to be for purposes of example only, and one skilled in the relevant arts will recognize that changes may be made to the embodiments described without departing from the scope of the invention disclosed. For example, the blocks and/or operations in the flowcharts and drawings described herein are for purposes of example only. There may be many variations to these blocks and/or operations without departing from the teachings of the present disclosure. For instance, the blocks may be performed in a differing order, or blocks may be added, deleted, or modified.

While illustrated in the block diagrams as groups of discrete components communicating with each other via distinct data signal connections, it will be understood by those skilled in the art that the present embodiments are provided by a combination of hardware and software components, with some components being implemented by a given function or operation of a hardware or software system, and many of the data paths illustrated being implemented by data communication within a computer application or operating system. Based on such understandings, the technical solution of the present invention may be embodied in the form of a software product. The software product may be stored in a non-volatile or non-transitory storage medium, which can be a read-only memory (ROM), a magnetic disk, an optical disc, a flash drive, or any other suitable storage media or device.

Each computer program described herein may be implemented in a high level procedural or object oriented programming or scripting language, or a combination thereof, to communicate with a computer system. Alternatively, the programs may be implemented in assembly or machine language. The language may be a compiled or interpreted language. The software product includes a number of instructions that enable a computer device (personal computer, server, or network device) to execute the methods provided in the embodiments of the present invention. Computer-executable instructions may be in many forms, including program modules, executed by one or more computers or other devices. Generally, program modules include routines, programs, objects, components, data structures, etc., that perform particular tasks or implement particular abstract data types. Typically the functionality of the program modules may be combined or distributed as desired in various embodiments. The structure illustrated is thus provided for efficiency of teaching the present embodiment. The present disclosure may be embodied in other specific forms without departing from the subject matter of the claims.

Also, one skilled in the relevant arts will appreciate that while the systems, methods and computer readable mediums disclosed and shown herein may comprise a specific number of elements/components, the systems, methods and computer readable mediums may be modified to include additional or fewer of such elements/components. The present disclosure is also intended to cover and embrace all suitable changes in technology. Modifications which fall within the scope of the present invention will be apparent to those skilled in the art, in light of a review of this disclosure, and such modifications are intended to fall within the appended claims.

What is claimed is:

1. A system for performing a test procedure, the system comprising:
a storage unit having stored therein the test procedure comprising one or more instructions for testing a system under test; and
a workstation remotely interfaced with the system under test, the workstation comprising a test unit configured to retrieve the test procedure from the storage unit and to simulate at least one operation on the system under test in real-time for testing the system under test in accordance with the one or more instructions.

2. The system of claim 1, wherein the test unit is configured to simulate the at least one operation comprising at least one of simulating a short to ground, disconnecting a connector, injecting a signal, injecting a voltage, injecting a current, simulating a resistance, simulating an impedance, simulating a capacitance, simulating an inductance, measuring a voltage, measuring a current, measuring a resistance, measuring an impedance, measuring a capacitance, and measuring an inductance.

3. The system of claim 1, wherein the system under test is an aircraft system selected from the group consisting of a hydraulics system, an engine system, a fuel system, a navigation system, a landing gear system, a flap control system, an electricity generating system, and a cabin climate control system.

4. The system of claim 3, wherein the storage unit has stored therein the one or more instructions comprising a first group of Functional Test Procedure (FTP) instructions and at least a second group of FTP instructions, the first group of FTP instructions comprising instructions for testing the aircraft system using the workstation, the second group of FTP instructions comprising at least one of instructions for testing the aircraft system without the workstation and instructions for inspecting an integrity of the aircraft system subsequent to the first group of FTP instructions being executed.

5. The system of claim 4, wherein the workstation further comprises at least one avionic test equipment and further wherein the first group of FTP instructions comprises a first subgroup comprising instructions for testing the aircraft system using the test unit and a second subgroup comprising instructions for testing the aircraft system using the at least one avionic test equipment.

6. The system of claim 1, wherein the test unit comprises a plurality of switches each actuatable for simulating the at least one operation.

7. The system of claim 1, wherein the test unit comprises:
at least one processing unit, and
a non-transitory memory communicatively coupled to the at least one processing unit and comprising computer-readable program instructions executable by the at least one processing unit for retrieving the test procedure from the storage unit and outputting a control signal comprising instructions for causing the at least one operation to be simulated on the system under test in accordance with the retrieved test procedure.

8. The system of claim 1, wherein the workstation is electrically interfaced with the system under test through at least one cable connecting each electrical connector of the system under test to the test unit.

9. The system of claim 3, further comprising at least one display device installed on the workstation, the at least one display device configured to display one or more images of at least one standby aircraft instrument for performing at least one visual check as part of the test procedure, the one or more images captured in real-time by at least one camera provided inside an aircraft having the aircraft system provided thereon.

10. The system of claim 1, further comprising a troubleshooting unit connected to the test unit and configured to automatically troubleshoot the system under test when the test unit determines that the at least one operation as simulated fails to satisfy one or more test criteria defined by the test procedure.

11. A method for performing a test procedure, the method comprising:
remotely interfacing a test unit with a system under test; and
using the test unit,
retrieving from a storage unit the test procedure comprising one or more instructions for testing the system under test, and
simulating at least one operation on the system under test in real-time for testing the system under test in accordance with the one or more instructions.

12. The method of claim 11, wherein simulating the at least one operation comprises at least one of simulating a short to ground, disconnecting a connector, injecting a signal, injecting a voltage, injecting a current, simulating a resistance, simulating an impedance, simulating a capacitance, simulating an inductance, measuring a voltage, measuring a current, measuring a resistance, measuring an impedance, measuring a capacitance, and measuring an inductance.

13. The method of claim 11, wherein remotely interfacing a test unit with the system under test comprises electrically interfacing the test unit with the system under test through at least one cable connecting each electrical connector of the system under test to the test unit.

14. The method of claim 11, further comprising integrating the test unit and at least one avionic test equipment on a workstation electrically interfaced with the system under test.

15. The method of claim 14, further comprising installing at least one display device on the workstation, the at least one display device configured to display one or more images of at least one standby aircraft instrument for performing at least one visual check as part of the test procedure, the one or more images captured in real-time by at least one camera provided inside an aircraft having the system under test provided thereon.

16. The method of claim 14, wherein the retrieved test procedure comprises a first group of Functional Test Procedure (FTP) instructions and at least a second group of FTP instructions for testing an aircraft system, the first group of FTP instructions comprising instructions for testing the aircraft system using the workstation, the second group of FTP instructions comprising at least one of instructions for testing the aircraft system without the workstation and instructions for inspecting an integrity of the aircraft system subsequent to the first group of FTP instructions being executed.

17. The method of claim 16, wherein the first group of FTP instructions comprises a first subgroup comprising instructions for testing the aircraft system using the test unit and a second subgroup comprising instructions for testing the aircraft system using at least one avionic test equipment.

18. The system of claim 11, wherein simulating the at least one operation comprises actuating one or more switches provided on the test unit.

19. The system of claim 11, further comprising automatically troubleshooting the system under test when the test unit determines that the at least one operation as simulated fails to satisfy one or more test criteria defined by the test procedure.

20. A non-transitory computer readable medium having stored thereon program code executable by a processor for:
retrieving from a storage unit a test procedure comprising one or more instructions for testing a system under test; and
simulating at least one operation on the system under test in real-time for testing the system under test in accordance with the one or more instructions.
